(19) United States
(12) Patent Application Publication
(10) Pub. No.: US 2015/0311361 A1
(43) Pub. Date: Oct. 29, 2015

(54) TRANSPARENT CONDUCTIVE GLASS SUBSTRATE WITH SURFACE ELECTRODE, METHOD FOR PRODUCING SAME, THIN FILM SOLAR CELL, AND METHOD FOR MANUFACTURING THIN FILM SOLAR CELL

(71) Applicant: SUMITOMO METAL MINING CO., LTD., Minato-ku, Tokyo (JP)

(72) Inventors: Kentaro SOGABE, Tokyo (JP); Yasunori YAMANOBE, Tokyo (JP); Fumihiko MATSUMURA, Tokyo (JP)

(73) Assignee: SUMITOMO METAL MINING CO., LTD., Minato-ku, Tokyo (JP)

(21) Appl. No.: 14/649,740

(22) PCT Filed: Oct. 11, 2013
(86) PCT No.: PCT/JP2013/077831

§ 371 Date: Jun. 4, 2015

(30) Foreign Application Priority Data
Dec. 4, 2012 (JP) 2012-265635

(51) Int. Cl. H01L 31/0224; H05K 1/03; H01L 31/18; H05K 1/02

(52) U.S. Cl. CPC H01L 31/022466; H05K 1/0274; H05K 1/0306; H01L 31/1884; H01L 31/022425; H01L 31/022483

(57) ABSTRACT

The present invention provides a transparent conductive glass substrate with a surface electrode having a low reflectivity, a low absorption, and a high transmittance, and provides a thin film solar cell including the surface electrode and having a higher photoelectric conversion efficiency than that of the prior arts. The transparent conductive glass substrate with the surface electrode is obtained in such a way that, on a translucent glass substrate, a low-refractive-index transparent thin film having a refractive index of 1.6 to 1.8 at a wavelength of 550 nm and a film thickness of 50 nm to 150 nm is formed as a first layer, and, on the low-refractive-index transparent thin film, an amorphous indium-oxide-based transparent conductive film as a second layer and a rough film made of a crystalline zinc-oxide-based transparent conductive film as a third layer are formed in that order.

### FIELD OF THE INVENTION

The present invention relates to a transparent conductive glass substrate with a surface electrode and a method for producing the same, the transparent conductive glass substrate being configured such that a surface electrode (film) comprising a transparent low-refractive-index film and a transparent conductive film is formed on a translucent glass substrate, and relates to a thin film solar cell including the transparent conductive glass substrate with the surface electrode and a method for manufacturing the thin film solar cell. The present application claims priority based on Japanese Patent Application No. 2012-265635 filed in Japan on Dec. 4, 2012. The total contents of the Patent Application are to be incorporated by reference into the present application.

### BACKGROUND ART

In a thin film solar cell that generates electricity by light incident from a translucent glass substrate, there is used a transparent conductive glass substrate configured such that one or a plurality of transparent conductive films made of tin oxide, zinc oxide, indium oxide, and the like are laminated as a light incident side electrode (hereinafter, referred to as a “surface electrode”) on a translucent substrate such as a glass substrate. Examples of a thin film solar cell include solar cells making use of a crystalline silicon thin film, such as polycrystalline silicon or microcrystal silicon, and solar cells making use of amorphous silicon thin film, and each of these thin film solar cells has been energetically developed, and, the development of these thin film solar cells aims to achieve both cost reduction and high performance by forming a good silicon thin film on an inexpensive substrate using a low-temperature process.

As one example of such thin film solar cells, there is known a thin film solar cell having a structure configured such that, on a translucent substrate, a surface electrode comprising a transparent conductive film, a photoelectric conversion semiconductor layer comprising a p-type semiconductor layer, an i-type semiconductor layer, and an n-type semiconductor layer which are laminated in that order, and a back surface electrode including a light reflective metal electrode are formed in that order.

In the thin film solar cell having such structure, a photoelectric conversion action occurs mainly in the i-type semiconductor layer, and therefore, in the case where the i-type semiconductor layer is thin, light in a long wavelength region having a small optical absorption coefficient is not sufficiently absorbed, and the amount of photoelectric conversion is essentially limited by the film thickness of the i-type semiconductor layer. Accordingly, in order to more effectively make use of light incident on a photoelectric conversion semiconductor layer including an i-type semiconductor layer, there has been given a scheme such that a surface roughness structure is provided to a surface electrode on the light incident side, whereby light is scattered into the photoelectric conversion semiconductor layer, and furthermore, reflected light undergoes irregular reflection on the back surface electrode.

In a silicon-based thin film solar cell having a surface roughness structure in a surface electrode on the light incident side, generally, as the surface electrode on the light incident side, there has been widely used a tin oxide film which is obtained by depositing a fluorine-doped tin-oxide thin film onto a glass substrate using a method of thermal decomposition of a source gas based on a thermal CVD method (for example, see Patent Literature 1).

However, a tin oxide film having a surface roughness structure causes high costs because of for example, requiring a high temperature process of not less than 500° C. Furthermore, there is a problem that such tin oxide film has a high specific resistance, and therefore, when the film thickness is made large to reduce the resistance value of the film, the transmittance is decreased, and photoelectric conversion efficiency is reduced.

Accordingly, there has been proposed a method being such that an Al-doped zinc oxide (AZO) film, or a Ga-doped zinc oxide (GZO) film is formed by sputtering on a base electrode made of a tin oxide film or a Sn-doped indium oxide (ITO) film, and a thus-formed zinc oxide film that can be easily etched is etched to form a surface electrode having a surface roughness structure (for example, see Patent Literature 2).

Alternatively, there has been proposed a method being such that an Ga- and Al-doped zinc oxide (GAZO) film, which leads to less arcing and less particle-generation at the time of the deposition is formed by sputtering on a base electrode made of a Ti-doped indium oxide film excellent in light transmittance in the near-infrared region, and as is the same with the foregoing Patent Literature 2, the zinc oxide film is etched to form a surface electrode having a surface roughness structure (for example, see Patent Literature 3).

Alternatively, there has been proposed a method being such that an amorphous transparent conductive film made of indium oxide is formed as a base film, and a crystalline transparent conductive film made of zinc oxide is formed on the base film (for example, see Patent Literature 4). This method allows a surface electrode made of a satisfactorily rough film to be formed without etching, and as a result, makes it possible to offer a surface electrode having a higher effect of optical confinement, and to achieve a thin film solar cell having a higher efficiency of photoelectric conversion.

Furthermore, there has been proposed a method being such that a film having an appropriate refractive index is laminated on a translucent glass substrate to prevent reflection and to increase transmitted light, whereby the amount of light to contribute to power generation is increased. Generally, an antireflective film having a conductive film is formed by alternately laminating a high-refractive-index film and a low-refractive-index film on a substrate (made of glass or a film) serving as a base. As a low-refractive index film, a silicon oxide (hereinafter, referred to as “SiO₂”) film is employed, meanwhile, as a high-refractive index conductive film, an indium tin oxide film (hereinafter, referred to as an “ITO film”, where ITO is an abbreviation of Indium Tin Oxide) is often employed. For example, there has been used a film in which an ITO film, a SiO₂ film, an ITO film, and a SiO₂ film are laminated in that order on a base film made of resin (for example, see Patent Literature 5).

### PRIOR-ART DOCUMENTS

### Patent Document

Patent document 1: Japanese Unexamined Patent Application Publication (Translation of PCT Application) No. H02-503615

Patent document 2: Japanese Patent Application Laid-Open No. 2000-294812

Patent document 3: Japanese Patent Application Laid-Open No. 2010-34232

Patent document 4: Japanese Patent Application Laid-Open No. 2012-009755

Patent document 5: Japanese Patent Application Laid-Open No. H09-197102

### SUMMARY OF THE INVENTION

### Problems to be Solved by the Invention

In consideration of the foregoing prior arts, in order to effectively achieve an optical confinement effect brought by a surface roughness structure and use a surface rough film as a transparent electrode for a thin film silicon solar cell having a high transmittance, it is necessary to prevent reflection between a glass substrate and the surface rough film thereby to efficiently introduce light into the rough film.

Accordingly, an object of the present invention is to provide a transparent conductive glass substrate with a surface electrode, having a low reflectivity, a low absorption, and a high transmittance, and to provide a thin film solar cell including the surface electrode and having a higher photoelectric conversion efficiency than that of the prior arts.

### Means to Solve the Problem

The inventors earnestly made a study to solve the problems of the prior arts. As a result, the inventors found that, before the formation of an indium-oxide-based transparent conductive film and a zinc-oxide-based transparent conductive film on a translucent glass substrate, a low-refractive-index transparent thin film having a refractive index of 1.6 to 1.8 at a wavelength of 550 nm is formed on the translucent glass substrate, whereby the difference in refractive index between layers is made small, and consequently, reflectivity is reduced without an increase in light absorption and transmittance is improved, and thus the inventors accomplished the present invention.

That is, a transparent conductive glass substrate with a surface electrode according to the present invention is characterized in that, on a translucent glass substrate, a low-refractive-index transparent thin film having a refractive index of 1.6 to 1.8 at a wavelength of 550 nm and having a film thickness of 50 nm to 150 nm is formed as a first layer, and an amorphous indium-oxide-based transparent conductive film as a second layer and a rough film made of a crystalline zinc-oxide-based transparent conductive film as a third layer are formed in that order on the low-refractive-index transparent thin film.

A method for producing a transparent conductive glass substrate with a surface electrode according to the present invention is characterized by comprising: a low-refractive-index transparent thin film formation step wherein a low-refractive-index transparent thin film having a refractive index of 1.6 to 1.8 at a wavelength of 550 nm and having a film thickness of 50 nm to 150 nm is formed as a first layer on a translucent glass substrate by sputtering; and a surface electrode formation step wherein, on the low-refractive-index transparent thin film, with the temperature of the translucent glass substrate being maintained in a range of not less than a room temperature and not more than 50° C., an amorphous indium-oxide-based transparent conductive film is formed as a second layer by sputtering, and then, with the temperature of the translucent glass substrate being maintained in a range of 250° C. to 400° C., a rough film made of a crystalline zinc-oxide-based transparent conductive film is formed as a third layer by sputtering.

A thin film solar cell according to the present invention comprises a transparent conductive glass substrate with a surface electrode, a photoelectric conversion semiconductor layer, and a back surface electrode including at least a light reflective metal electrode which are formed in that order, the transparent conductive glass substrate being configured such that, on a translucent glass substrate, a low-refractive-index transparent thin film having a refractive index of 1.6 to 1.8 at a wavelength of 550 nm and having a film thickness of 50 nm to 150 nm is formed as a first layer, and an amorphous indium-oxide-based transparent conductive film as a second layer and a rough film made of a crystalline zinc-oxide-based transparent conductive film as a third layer are formed in that order on the low-refractive-index transparent thin film.

A method for manufacturing a thin film solar cell according to the present invention includes a formation step of a transparent conductive glass substrate with a surface electrode, the thin film solar cell comprising a transparent conductive glass substrate with a surface electrode, a photoelectric conversion semiconductor layer, and a back surface electrode including at least a light reflective metal electrode which are formed in that order, wherein the formation step of the transparent conductive glass substrate with the surface electrode comprises: a low-refractive-index transparent thin film formation step wherein a low-refractive-index transparent thin film having a refractive index of 1.6 to 1.8 at a wavelength of 550 nm and having a film thickness of 50 nm to 150 nm is formed as a first layer on a translucent glass substrate by sputtering; and a surface electrode formation step wherein, on the low-refractive-index transparent thin film, with the temperature of the translucent glass substrate being maintained in a range of not less than a room temperature and not more than 50° C., an amorphous indium-oxide-based transparent conductive film is formed as a second layer by sputtering, and then, with the temperature of the translucent glass substrate being maintained in a range of 250° C. to 400° C., a rough film made of a crystalline zinc-oxide-based transparent conductive film is formed as a third layer by sputtering.

### Effects of Invention

The transparent conductive glass substrate with the surface electrode according to the present invention is allowed to achieve a satisfactorily rough film without etching, and as a result, there is achieved a surface electrode that is a transparent conductive electrode having a lower reflectivity and a more excellent transmittance than that of the prior arts and has a higher effect of optical confinement. The use of this surface electrode makes it possible to configure a thin film solar cell having a higher photoelectric conversion efficiency.

### BRIEF DESCRIPTION OF DRAWINGS

FIG. 1 is a cross-sectional view illustrating an example of a thin film solar cell.

FIG. 2 is a chart illustrating a relationship between a molar ratio of Si to In in an ISiO film constituting a low-refractive-index transparent thin film and a refractive index of the ISiO film.

### DETAILED DESCRIPTION OF THE INVENTION

Hereinafter, a specific embodiment of a transparent conductive glass substrate with a surface electrode according to the present invention and a thin film solar cell adopting the transparent conductive glass substrate (hereinafter referred to as “the present embodiment”) will be described in detail with reference to the drawings.

[1. Configuration of Thin Film Solar Cell]

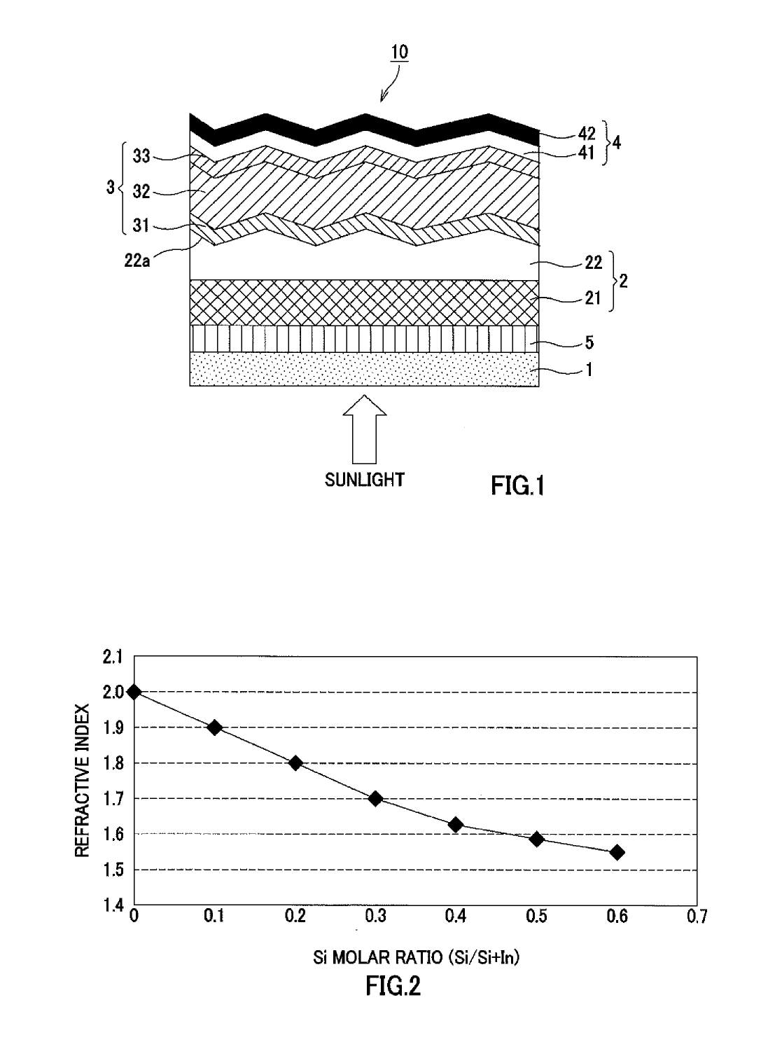

FIG. 1 is a schematic cross-sectional view of a thin film solar cell 10 adopting a transparent conductive glass substrate with a surface electrode according to the present embodiment.

As illustrated in FIG. 1, the thin film solar cell 10 has a structure configured such that a translucent glass substrate 1, a low-refractive-index transparent thin film 5, a surface electrode 2, a photoelectric conversion semiconductor layer 3, and a back surface electrode 4 are laminated in that order. In the thin film solar cell 10, the surface electrode 2 formed on the low-refractive-index transparent thin film 5 is configured with a base film 21 and a rough film 22. The photoelectric conversion semiconductor layer 3 formed on the surface electrode 2 is configured with a p-type semiconductor layer 31, an i-type semiconductor layer 32, and an n-type semiconductor layer 33 which are laminated in that order. The back surface electrode 4 is configured with a transparent conductive oxide film 41 and a light reflective metal electrode 42. In the thin film solar cell 10, as indicated by an outline arrow in FIG. 1, light to be photoelectrically converted enters through the translucent glass substrate 1 side.

[2. Translucent Glass Substrate]

As the translucent glass substrate 1, there may be used a transparent glass substrate made of soda lime silicate glass, borate glass, low-alkali-containing glass, quartz glass, or other various glasses.

This translucent glass substrate 1 preferably has a high transmittance in a wavelength range of 350 to 1200 nm so as to allow light in the sunlight spectrum to penetrate. Furthermore, in consideration of the use under outdoor environment conditions, the translucent glass substrate 1 is preferably electrically, chemically, and physically stable. Furthermore, in the translucent glass substrate 1, in order to prevent ions from diffusing from the glass to the surface electrode 2 made of a transparent conductive film that is deposited on the substrate and to minimize the effects of the type and the surface state of the glass substrate on the electrical characteristics of the film, an alkali barrier film such as a silicon oxide film may be provided on the glass substrate.

[3. Low-Refractive-Index Transparent Thin Film]

The low-refractive-index transparent thin film 5 is a transparent thin film having a refractive index of 1.6 to 1.8 at a wavelength of 550 nm. The composition of the low-refractive-index transparent thin film 5 is not particularly limited as long as the refractive index is in the foregoing range, but, an oxide film of indium (In) and silicon (Si) is preferable. The oxide film of In and Si is a low-refractive-index transparent thin film having a refractive index of 1.6 to 1.8 at a wavelength of 550 nm, and specifically, an oxide film having a composition having a molar ratio of Si to In, (Si/Si+In), of from 0.2 to 0.5 has a refractive index of 1.6 to 1.8.

Furthermore, the oxide film of In and Si can be formed by DC magnetron sputtering using a target material obtained by forming and sintering a raw material powder made of a mixture of indium oxide, silicon oxide, and metal silicon. Such method allows the formation of a film that is an insulating material and suitable for mass production.

Here, FIG. 2 illustrates a relationship between a molar ratio of Si to In, (Si/Si+In), and a refractive index of a transparent thin film (oxide film) deposited by DC sputtering. As shown in FIG. 2, it is understood that, when Si is not doped, the transparent thin film has a refractive index of 2.0, which is equivalent to the refractive indexes of an ITiO film and an ITiTO film, but, as the amount of Si doped increases, the refractive index of the transparent thin film is closer to the refractive index of SiO₂. However, a silicon molar ratio of more than 0.6 causes difficulties in synthesis of a high-density target and difficulties in deposition excellent in mass production.

Furthermore, from the viewpoint of improving the transmittance, the low-refractive-index transparent thin film 5 preferably has a film thickness of 50 to 150 nm. When the film thickness is less than 50 nm, the surface electrode 2 made of a transparent conductive film having a haze ratio of not less than 10% cannot be formed on the low-refractive-index transparent thin film 5. Also when the film thickness is more than 150 nm, the surface electrode 2 does not have a haze ratio of not less than 10%, that is, has a considerably low haze ratio.

Furthermore, the low-refractive-index transparent thin film 5 preferably has smoothness, namely a surface roughness Ra (arithmetic mean roughness) of not more than 1.0 nm. A low-refractive-index transparent thin film 5 having a surface roughness Ra of more than 1.0 nm has an adverse effect on the film quality of the late-described base film 21, and inhibits the growth of zinc oxide crystals in the rough film 22, and as a result, the surface electrode 2 does not have a haze ratio of not less than 10%, that is, has a considerably low haze ratio.

[4. Surface Electrode]

The surface electrode 2 is provided on the low-refractive-index transparent thin film 5 deposited as a first layer on the translucent glass substrate 1, and is configured with the base film 21 and the rough film 22 which are laminated in that order. In other words, a transparent conductive glass substrate with a surface electrode is configured such that, on the translucent glass substrate 1, the low-refractive-index transparent thin film 5 as a first layer, the base film 21 as a second layer, and the rough film as a third layer are formed in that order.

As is the case with the translucent glass substrate 1, the surface electrode 2 preferably has a high transmittance of not less than 80% to light having a wavelength of 350 to 1200 nm, more preferably has a transmittance of not less than 85% to light having the foregoing wavelength. Furthermore, the thickness of the surface electrode 2 is preferably adjusted so that the sheet resistance is not more than 10 Ω/sq. As for the following parameters, the parameters will be described by taking an example of high specifications for a transparent electrode for thin film solar cells to aim at achieving a transmittance of not less than 85% and a sheet resistance of not more than 10 Ω/sq. as mentioned above.

[4-1. Base Film]

For the base film 21 constituting the surface electrode 2, an amorphous indium-oxide-based transparent conductive film is employed. From the viewpoint of achieving a higher transmittance to light in the near-infrared region, out of indium-oxide-based transparent conductive films, a titanium (Ti)-doped indium oxide film (hereinafter, abbreviated an “ITiO film”) is preferably employed. Another reason why an ITiO film is preferably employed is that an ITiO film allows an amorphous film to be easily obtained and the growth of zinc oxide crystals in the later-described rough film 22 to be promoted. Furthermore, out of indium-oxide-based transparent conductive films, a film obtained by further doping an ITiO film with tin (Sn) (hereinafter, abbreviated an “ITiTO film”) is more preferable than an ITiO film because the growth of zinc oxide crystals in the rough film 22 can be further promoted.

The thickness of the base film 21 is not particularly limited, but, preferably 60 to 400 nm, more preferably 100 to 200 nm. In the case where the base film 21 has a thickness of less than 60 nm, an effect of increasing a haze ratio by the base film 21 is considerably reduced, on the other hand, in the case where the base film 21 has a thickness of more than 400 nm, a decrease in transmittance cancels out an effect of optical confinement by an increase in haze ratio. The more preferable film thickness of 100 to 200 nm allows a haze ratio as a characteristic of the surface electrode 2 to be increased to not less than 10%, and also allows the surface electrode 2 having a high transmittance to be foamed.

In the deposition of the base film 21 made of an amorphous indium-oxide-based transparent conductive film, it is important that, for example, as described in Patent Literature 4, the translucent glass substrate 1 is cooled to inhibit crystallization in the base film 21 and make the base film 21 amorphous. Specifically, with the temperature of the translucent glass substrate 1 being maintained in a range of not less than a room temperature and not more than 50° C., the deposition of the base film 21 is carried out by a method such as sputtering. Furthermore, in order to increase the crystallization temperature and thereby to more reliably make the base film 21 amorphous, the partial pressure of water in a chamber at the time of sputtering is preferably maintained in the 10⁻² Pa range.

[4-2. Rough Film]

The rough film 22 which is a constituent of the surface electrode 2 is deposited on the foregoing base film 21 made of an amorphous indium-oxide-based transparent conductive film, and is made of a crystalline zinc-oxide-based transparent conductive film. The formation of roughness in the surface roughness structure 22a of the rough film 22 can be controlled by the amorphous level of the amorphous base film 21 and sputtering conditions, such as gas pressure and DC electric power at the time of sputtering, and the amorphous characteristic of the foregoing base film 21 is an important parameter. Specifically, as for the degree of roughness in the surface roughness structure 22a of the rough film 22, the structure preferably has a roughness that satisfies a haze ratio of not less than 10% and an arithmetic mean roughness (Ra) of 30 to 100 nm.

Furthermore, as long as containing zinc oxide as a main component (not less than 90% by weight), the rough film 22 may be doped with an additive metal element. Examples of the element with which a zinc oxide film is doped include Al, Ga, B, In, F, Si, Ge, Ti, Zr, and Hf. Out of the zinc oxide films doped with an additive metal element, a zinc oxide film doped with Al or Ga, or a zinc oxide film doped with both Al and Ga (hereinafter, abbreviated an “GAZO film”) is more preferable because such film causes arcing to hardly occur at the time of the deposition of the film by sputtering.

The film thickness of the rough film 22 is not particularly limited, but, preferably 400 to 1500 nm, more preferably 500 to 1200 nm. When the film thickness is within such range, a rough film having desired characteristics can be achieved. When the film thickness is less than 400 nm, projections and depressions are inhibited from becoming sufficiently large, and accordingly the haze ratio of the film is sometimes less than 10%. On the other hand, when the film thickness is more than 1500 nm, the transmittance is very low. Furthermore, the more preferable film thickness of 500 to 1200 nm allows a haze ratio of not less than 10% to be surely achieved, and also allows the surface electrode 2 having a high transmittance to be formed.

The deposition of the rough film 22 made of a crystalline zinc-oxide-based conductive film needs to be carried out by sputtering with the temperature of the translucent glass substrate 1 being maintained in a range of 250° C. to 400° C. When the temperature of the translucent glass substrate 1 is less than 250° C., the crystallization of zinc oxide does not proceed during the deposition of the zinc oxide film, and accordingly a rough film having a haze ratio of not less than 10% is not be formed. On the other hand, a substrate temperature of more than 400° C. is beneficial to the crystallization of the zinc oxide film, but, causes the amorphous characteristic of the base film 21 to be worse or the c-axis orientation of the zinc oxide film constituting the rough film 22 to be stronger and thereby the rough film 22 to have a flat surface, and possibly therefore a rough film having a haze ratio of not less than 10% is hard to be obtained.

[5. Photoelectric Conversion Semiconductor Layer]

The photoelectric conversion semiconductor layer 3 is formed on the foregoing surface electrode 2. This photoelectric conversion semiconductor layer 3 is configured with, for example, a p-type semiconductor layer 31, an i-type semiconductor layer 32, and a n-type semiconductor layer 33 which are laminated in that order. It should be noted that the n-type semiconductor layer 33 and the p-type semiconductor layer 31 may be laminated in that order, but, in a solar cell, usually a p-type semiconductor layer is arranged at the light incident side.

The p-type semiconductor layer 31 is made of a microcrystalline silicon thin film doped with an impurity atom such as boron (B). The impurity atom employed as a dopant is not particularly limited, but, in the case of the p-type semiconductor, aluminum (Al) may be beneficial. Furthermore, instead of microcrystal silicon, polycrystalline silicon or amorphous silicon, or an alloy material, such as silicon carbide or silicon germanium, may be employed. It should be noted that, as needed, a deposited semiconductor layer may be irradiated with a pulsed laser beam (laser annealing) to control a crystallization fraction or a carrier concentration.

The i-type semiconductor layer 32 is made of a non-doped microcrystalline silicon thin film. As the i-type semiconductor layer 32, there may be employed polycrystalline silicon or amorphous silicon, or a silicon-based thin film material which is a weak p-type or a weak n-type semiconductor containing trace impurities and has a sufficient photoelectric conversion function. Furthermore, the i-type semiconductor layer 32 is not limited to these materials, and, besides microcrystalline silicon, an alloy material, such as silicon carbide or silicon germanium, may be also used.

The n-type semiconductor layer 33 formed on the i-type semiconductor layer 32 is made of a thin film made of microcrystalline silicon, polycrystalline silicon, amorphous silicon, or an alloy material such as silicon carbide or silicon germanium, each of which is a n-type doped with an impurity atom such as phosphorus (P). The impurity atom employed as a dopant is not particularly limited, but, in the case of the n-type semiconductor, nitrogen (N) may be beneficial.

The photoelectric conversion semiconductor layer 3 having such configuration can be formed, for example, using a plasma CVD method with a base material temperature being set to not more than 400° C. The plasma CVD method to be used is not particularly limited, and a commonly well-known parallel-plate-type RF plasma CVD may be employed, alternatively, a plasma CVD method using a high frequency power source in a range of from the RF band to the VHF band in a frequency of not more than 150 MHz may be employed.

[6. Back Surface Electrode]

The back surface electrode 4 is formed on the n-type semiconductor layer 33 constituting the foregoing photoelectric conversion semiconductor layer 3. This back surface electrode 4 is configured with, for example, a transparent conductive oxide film 41 and a light reflective metal electrode 42 which are laminated in that order.

The transparent conductive oxide film 41 is not necessarily required, but, has a function of increasing the adhesion between the foregoing n-type semiconductor layer 33 and the light reflective metal electrode 42, thereby increasing the reflection efficiency of the light reflective metal electrode 42, and preventing a chemical change of the n-type semiconductor layer 33.

Furthermore, the transparent conductive oxide film 41 is made of for example, at least one kind selected from a zinc oxide film, an indium oxide film, a tin oxide film, and the like. Particularly, it is preferable that, in the case of a zinc oxide film, the film is doped with at least one kind of Al and Ga, and, in the case of an indium oxide film, the film is doped with at least one kind of Sn, Ti, W, Ce, Ga, and Mo, whereby a transparent conductive film having a higher conductivity is achieved. Furthermore, the transparent conductive oxide film 41 adjoining the n-type semiconductor layer 33 preferably has a specific resistance of not more than 1.5×10⁻³ Ωcm.

The light reflective metal electrode 42 is preferably formed by a method, such as vacuum deposition or sputtering, and made of one kind selected from Ag, Au, Al, Cu, and Pt, or an alloy containing these. It is beneficial that the light reflective metal electrode 42 is formed, for example, by vacuum deposition of Ag, which has a high light reflectivity, at a temperature of 100 to 330° C., more preferably at a temperature of 200 to 300° C.

### EXAMPLES

Hereinafter, Examples according to the present invention will be described by comparing with Comparative Examples. It should be noted that the present invention is not limited to these Examples.

<Evaluation method>

(1) Film-thickness was measured in the following procedure. That is, an oil-based marking ink was applied beforehand to a part of a substrate before deposition, then, after the deposition, the oil-based marking ink was removed by ethanol to form a non-coated portion, and the difference in height between the non-coated portion and a coated portion was measured and determined using a contact type surface profiler (Alpha-Step IQ, manufactured by KLA-Tencor Corporation).

(2) Sheet resistance was measured by a four-probe method using a resistivity meter, Loresta EP (MCP-T360, manufactured by DIA INSTRUMENTS, CO., LTD.).

(3) Haze ratio was evaluated, based on Japanese Industrial Standard (HS) K7136, using a haze meter (HM-150, manufactured by MURAKAMI COLOR RESEARCH LABORATORY Co., Ltd.).

(4) Light transmittance was measured using a spectrophotometer (U-4000, manufactured by Hitachi, Ltd.).

### Example 1

Under the following manufacturing conditions, a silicon-based thin film solar cell having a structure illustrated in FIG. 1 was prepared.

(Evaluation of Surface Electrode)

First, using a sintered compact made of a synthetic powder of indium oxide, silicon oxide, and silicon as a low-refractive-index transparent thin film 5, an ISiO film having a film thickness of 50 nm was formed on a soda lime silicate glass substrate used as a translucent glass substrate 1 by DC sputtering. At this time, a Si composition was adjusted to 0.2 at a molar ratio with respect to In. It should be noted that, after the deposition of the ISiO film, the film had a surface roughness (arithmetic mean roughness (Ra)) of 0.5 nm. Table 1 shows deposition conditions and the surface roughness of the low-refractive-index transparent thin film 5.

Next, on the low-refractive-index transparent thin film 5, a surface electrode 2 configured with a base film 21 made of an ITiO film and a rough film 22 made of a GAZO film was formed. As the ITiO film constituting the base film 21, there was employed a film obtained by doping indium oxide with 1% by mass of titanium oxide, and, as the GAZO film constituting the rough film 22, there was employed a film obtained by doping zinc oxide with 0.58% by mass of gallium oxide and 0.32% by mass of aluminum oxide.

Specifically, the base film 21 made of the ITiO film was deposited by sputtering using a mixed gas of argon and oxygen (argon:oxygen=99:1) as introduced gas with a temperature of translucent glass substrate 1 being set to 25° C. so that the ITiO film had a film thickness of 100 nm. Next, with a temperature of the translucent glass substrate 1 being set to 300° C., the GAZO film was formed using 100% argon gas as an introduced gas at a sputtering power of DC 400 W so as to have a film thickness of 500 nm. It should be noted that Table 1 shows deposition conditions for the surface electrode 2.

The thus obtained surface electrode 2 had an arithmetic mean roughness (Ra) of 63 nm. Table 2 shows the characteristics of the obtained surface electrode 2. As shown in Table 2, the surface electrode 2 had a sheet resistance value of 9.1 Ω/sq. and a haze ratio of 15%.

(Evaluation of Thin Film Solar Cell)

Next, on the foregoing surface electrode 2, a p-type semiconductor layer 31 made of a boron-doped p-type microcrystalline silicon layer having a thickness of 10 nm, an i-type semiconductor layer 32 made of an i-type microcrystalline silicon layer having a thickness of 3 μm, and a p-type semiconductor layer 33 made of a phosphorus-doped n-type microcrystalline silicon layer having a thickness of 15 nm were deposited in that order by a plasma CVD method to form a pin junction photoelectric conversion semiconductor layer 3.

Then, on the photoelectric conversion semiconductor layer 3, there was deposited, by sputtering, a back surface electrode 4 that comprises a transparent conductive oxide film 41 made of a GAZO film and having a thickness of 70 nm and a light reflective metal electrode 42 made of Ag and having a thickness of 300 nm. As the transparent conductive oxide film 41, there was employed a film obtained by doping zinc oxide with 2.3% by weight of gallium oxide and 1.2% by weight of aluminum oxide.

The thus-obtained thin film solar cell was irradiated with AM (air mass) 1.5 light at a light amount of 100 mW/cm² to measure a photoelectric conversion efficiency at 25° C. As a result, as shown in Table 2, the thin film solar cell had a photoelectric conversion efficiency of 10.3%.

### Examples 2 to 4

In Example 2, the film thickness of the base film 21 which was a constituent of the surface electrode 2 was changed to 200 nm; in Example 3, the film thickness of the rough film 22 which was a constituent of the surface electrode 2 was changed to 1200 nm; and in Example 4, the film thickness of the base film 21 and the film thickness of the rough film 22 were changed to 200 nm and 1200 nm, respectively. Except those, the surface electrode 2 in each of Examples 2 to 4 was formed in the same manner as in Example 1, and the characteristics thereof were evaluated. Table 2 shows the respective evaluation results.

As shown in Table 2, the surface electrodes 2 obtained in Examples 2 to 4 had sheet resistance values of 8.5 Ω/sq., 8.8 Ω/sq., and 8.3 Ω/sq., respectively, and haze ratios of 18%, 20%, and 21%, respectively.

Furthermore, using the respective surface electrodes 2 formed in Examples 2 to 4, thin film solar cells were formed in the same manner as in Example 1, and the characteristics thereof were evaluated. As a result, as shown in Table 2, the thin film solar cells formed in Examples 2 to 4 had photoelectric conversion efficiencies of 10.3%, 10.5%, and 10.4%, respectively.

### Examples 5 to 8

In Example 5, a surface electrode 2 was formed in the same manner as in Example 1 and the characteristics thereof were evaluated, except that the film thickness of the ISiO film constituting the low-refractive-index transparent thin film 5 was changed to 100 nm. In Example 6, the film thickness of the base film 21 which was a constituent of the surface electrode 2 was changed to 200 nm; in Example 7, the film thickness of the rough film 22 which was a constituent of the surface electrode 2 was changed to 1200 nm; and in Example 8, the film thickness of the base film 21 and the film thickness of the rough film 22 were changed to 200 nm and 1200 nm, respectively. Except those, the surface electrode 2 in each of Examples 6 to 8 was formed in the same manner as in Example 5, and the characteristics thereof were evaluated. Table 2 shows the respective evaluation results.

As shown in Table 2, the surface electrodes 2 obtained in Examples 5 to 8 had sheet resistance values of 8.8 Ω/sq., 8.7 Ω/sq., 8.8 Ω/sq., and 8.9 Ω/sq., respectively, and haze ratios of 15%, 16%, 23%, and 22%, respectively.

Furthermore, using the respective surface electrodes 2 formed in Examples 5 to 8, thin film solar cells were formed in the same manner as in Example 1, and the characteristics thereof were evaluated. As a result, as shown in Table 2, the thin film solar cells formed in Examples 5 to 8 had photoelectric conversion efficiencies of 10.6%, 10.7%, 10.6% and 10.6%, respectively.

### Examples 9 to 12

In Example 9, a surface electrode 2 was formed in the same manner as in Example 1 and the characteristics thereof were evaluated, except that the film thickness of the ISiO film constituting the low-refractive-index transparent thin film 5 was changed to 150 nm. In Example 10, the film thickness of the base film 21 which was a constituent of the surface electrode 2 was changed to 200 nm; in Example 11, the film thickness of the rough film 22 which was a constituent of the surface electrode 2 was changed to 1200 nm; and in Example 12, the film thickness of the base film 21 and the film thickness of the rough film 22 were changed to 200 nm and 1200 nm, respectively. Except those, the surface electrode 2 in each of Examples 10 to 12 was formed in the same manner as in Example 9, and the characteristics thereof were evaluated. Table 2 shows the respective evaluation results.

As shown in Table 2, the surface electrodes 2 obtained in Examples 9 to 12 had sheet resistance values of 8.6 Ω/sq., 8.9 Ω/sq., 8.7 Ω/sq., and 8.5 Ω/sq., respectively, and haze ratios of 17%, 18%, 20%, and 21%, respectively.

Furthermore, using the respective surface electrodes 2 formed in Examples 9 to 12, thin film solar cells were foamed in the same manner as in Example 1, and the characteristics thereof were evaluated. As a result, as shown in Table 2, all the thin film solar cells formed in Examples 9 to 12 had a photoelectric conversion efficiency of 10.4%.

### Examples 13 to 16

In Example 13, a surface electrode 2 was formed in the same manner as in Example 1 and the characteristics thereof were evaluated, except that, in the deposition of the low-refractive-index transparent thin film 5, an ISiO film was formed using a sintered compact in which a Si composition was adjusted to 0.5 at a molar ratio with respect to In. In Example 14, the film thickness of the base film 21 which was a constituent of the surface electrode 2 was changed to 200 nm; in Example 15, the film thickness of the rough film 22 which was a constituent of the surface electrode 2 was changed to 1200 nm; and in Example 16, the film thickness of the base film 21 and the film thickness of the rough film 22 were changed to 200 nm and 1200 nm, respectively. Except those, the surface electrode 2 in each of Examples 14 to 16 was formed in the same manner as in Example 13, and the characteristics thereof were evaluated. Table 2 shows the respective evaluation results.

As shown in Table 2, the surface electrodes 2 obtained in Examples 13 to 16 had sheet resistance values of 8.3 Ω/sq., 8.2 Ω/sq., 8.0 Ω/sq., and 8.8 Ω/sq., respectively, and haze ratios of 20%, 21%, 22%, and 20%, respectively.

Furthermore, using the respective surface electrodes 2 formed in Examples 13 to 16, thin film solar cells were formed in the same manner as in Example 1, and the characteristics thereof were evaluated. As a result, as shown in Table 2, the thin film solar cells formed in Examples 13 to 16 had photoelectric conversion efficiencies of 10.8%, 10.8%, 10.7%, and 10.8%, respectively.

### Examples 17 to 20

In Example 17, a surface electrode 2 was formed in the same manner as in Example 1 and the characteristics thereof were evaluated, except that, in the deposition of the low-refractive-index transparent thin film 5 as the first layer, an ISiO film having a film thickness of 100 nm was formed using a sintered compact in which a Si composition was adjusted to 0.5 at a molar ratio with respect to In. In Example 18, the film thickness of the base film 21 which was a constituent of the surface electrode 2 was changed to 200 nm; in Example 19, the film thickness of the rough film 22 which was a constituent of the surface electrode 2 was changed to 1200 nm; and in Example 20, the film thickness of the base film 21 and the film thickness of the rough film 22 were changed to 200 nm and 1200 nm, respectively. Except those, the surface electrode 2 in each of Examples 18 to 20 was formed in the same manner as in Example 17, and the characteristics thereof were evaluated. Table 2 shows the respective evaluation results.

As shown in Table 2, the surface electrodes 2 obtained in Examples 17 to 20 had sheet resistance values of 8.2 Ω/sq., 7.8 Ω/sq., 9.0 Ω/sq., and 7.7 Ω/sq., respectively, and haze ratios of 18%, 19%, 14%, and 17%, respectively.

Furthermore, using the respective surface electrodes 2 formed in Examples 17 to 20, thin film solar cells were formed in the same manner as in Example 1, and the characteristics thereof were evaluated. As a result, as shown in Table 2, all the thin film solar cells formed in Examples 17 to 20 had a photoelectric conversion efficiency of 10.4%.

### Examples 21 to 24

In Example 21, a surface electrode 2 was formed in the same manner as in Example 1 and the characteristics thereof were evaluated, except that, in the deposition of the low-refractive-index transparent thin film 5, an ISiO film having a film thickness of 150 nm was formed using a sintered compact in which a Si composition was adjusted to 0.5 at a molar ratio with respect to In. In Example 22, the film thickness of the base film 21 which was a constituent of the surface electrode 2 was changed to 200 nm; in Example 23, the film thickness of the rough film 22 which was a constituent of the surface electrode 2 was changed to 1200 nm; and in Example 24, the film thickness of the base film 21 and the film thickness of the rough film 22 were changed to 200 nm and 1200 nm, respectively. Except those, the surface electrode 2 in each of Examples 22 to 24 was formed in the same manner as in Example 21, and the characteristics thereof were evaluated. Table 2 shows the respective evaluation results.

As shown in Table 2, the surface electrodes 2 obtained in Examples 21 to 24 had sheet resistance values of 8.6 Ω/sq., 8.7 Ω/sq., 8.9 Ω/sq., and 8.7 Ω/sq., respectively, and haze ratios of 15%, 13%, 14%, and 18%, respectively.

Furthermore, using the respective surface electrodes 2 formed in Examples 21 to 24, thin film solar cells were formed in the same manner as in Example 1, and the characteristics thereof were evaluated. As a result, as shown in Table 2, the thin film solar cells formed in Examples 21 to 24 had photoelectric conversion efficiencies of 10.8%, 10.9%, 10.3%, and 10.6%, respectively.

### Comparative Examples 1 and 2

In Comparative Examples 1 and 2, the respective surface electrodes 2 were formed in the same manner as in Example 1 and the characteristics thereof were evaluated, except that, in the deposition of the low-refractive-index transparent thin film 5 as the first layer, in Comparative Example 1, an ISiO film had a film thickness of 30 nm, and, in Comparative Example 2, an ISiO film had a film thickness of 200 nm. It should be noted that, in Comparative Example 2, the formed ISiO film had a surface roughness (arithmetic mean roughness Ra) was 1.1 nm, that is, had poor smoothness. Table 2 shows the respective evaluation results.

As shown in Table 2, the surface electrodes 2 obtained in Comparative Examples 1 and 2 had sheet resistance values of 8.3 Ω/sq. and 8.2 Ω/sq., respectively, but had low haze ratios of 9% and 7%, respectively.

Furthermore, using the respective surface electrodes 2 formed in Comparative Examples 1 and 2, the respective thin film solar cells were formed in the same manner as in Example 1, and the characteristics thereof were evaluated. As a result, each of the thin film solar cells formed in Comparative Examples 1 and 2 had a low photoelectric conversion efficiency of 9.2%.

### Comparative Examples 3 and 4

In Comparative Examples 3 and 4, the respective surface electrodes 2 were formed in the same manner as in Example 1 and the characteristics thereof were evaluated, except that, in the deposition of the low-refractive-index transparent thin film 5 as the first layer, ISiO films having film thicknesses of 30 nm and 200 nm were deposited, respectively, using a sintered compact in which a Si composition was adjusted to 0.5 at a molar ratio with respect to In. It should be noted that, in Comparative Example 4, the formed ISiO film had a surface roughness (arithmetic mean roughness Ra) of 1.2 nm, that is, had poor smoothness. Table 2 shows the respective evaluation results.

As shown in Table 2, the surface electrodes 2 obtained in Comparative Examples 3 and 4 had sheet resistance values of 8.3 Ω/sq. and 8.1 Ω/sq., respectively, but had very low haze ratios of 7% and 3%, respectively.

Furthermore, using the respective surface electrodes 2 formed in Comparative Examples 3 and 4, the respective thin film solar cells were formed in the same manner as in Example 1, and the characteristics thereof were evaluated. As a result, the respective thin film solar cells formed in Comparative Examples 3 and 4 had a low photoelectric conversion efficiency of 9.3%.

### Comparative Examples 5 and 6

In Comparative Examples 5 and 6, the respective surface electrodes 2 were formed in the same manner as in Example 1 and the characteristics thereof were evaluated, except that, in the deposition of the low-refractive-index transparent thin film 5 as the first layer, the respective ISiO films having film thicknesses of 50 nm and 150 nm were formed using a sintered compact in which a Si composition was adjusted to 0.1 at a molar ratio with respect to In. Table 2 shows the respective evaluation results.

As shown in Table 2, the surface electrodes 2 obtained in Comparative Examples 5 and 6 had sheet resistance values of 8.1 Ω/sq. and 8.2 Ω/sq., respectively, but had very low haze ratios of 3% and 2%, respectively.

Furthermore, using the respective surface electrodes 2 formed in Comparative Examples 5 and 6, the respective thin film solar cells were formed in the same manner as in Example 1, and the characteristics thereof were evaluated. As a result, the respective thin film solar cells formed in Comparative Examples 5 and 6 had a low photoelectric conversion efficiency of 9.1%.

### Comparative Examples 7 and 8

In Comparative Examples 7 and 8, the respective surface electrodes 2 were formed in the same manner as in Example 1 and the characteristics thereof were evaluated, except that, in the deposition of the low-refractive-index transparent thin film 5 as the first layer, the respective ISiO films having film thicknesses of 50 nm and 150 nm were formed using a sintered compact in which a Si composition was adjusted to 0.6 at a molar ratio with respect to In. It should be noted that the ISiO films as the first layer had a refractive index of 1.55. Table 2 shows the respective evaluation results.

As shown in Table 2, the surface electrodes 2 obtained in Comparative Examples 7 and 8 had sheet resistance values of 8.4 Ω/sq. and 7.9 Ω/sq., respectively, but had low haze ratios of 7% and 8%, respectively. Furthermore, the surface electrodes 2 obtained in Comparative Examples 7 and 8 had low transmittances of 79.8% and 79.7%, respectively.

Furthermore, using the respective surface electrodes 2 formed in Comparative Examples 7 and 8, the respective thin film solar cells were formed in the same manner as in Example 1, and the characteristics thereof were evaluated. As a result, the respective thin film solar cells formed in Comparative Examples 7 and 8 had a low photoelectric conversion efficiency of 9.0%.

### Comparative Example 9

In Comparative Example 9, without the deposition of an ISiO film constituting the low-refractive-index transparent thin film 5 as the first layer, a surface electrode 2 comprising a base film 21 made of an ITiO film and a rough film 22 made of a GAZO film was formed on a translucent glass substrate 1, and the characteristics of the surface electrode 2 were evaluated. It should be noted that the surface electrode 2 was formed in the same manner as in Example 1. Table 2 shows the evaluation results.

As shown in Table 2, the obtained surface electrode 2 had a very low transmittance of 78.5%.

Furthermore, using the surface electrode 2 formed in Comparative Example 9, a thin film solar cell was formed in the same manner as in Example 1, and the characteristics thereof were evaluated. As a result, the thin film solar cell had a very low photoelectric conversion efficiency of 8.7%.

### Comparative Examples 10 and 11

In Comparative Examples 10 and 11, the respective surface electrodes 2 were formed in the same manner as in Example 1 and the characteristics thereof were evaluated, except that base films 21 constituting the surface electrodes 2 formed in Comparative Examples 10 and 11 had film thicknesses of 40 nm and 250 nm, respectively. Table 2 shows the respective evaluation results.

As shown in Table 2, the surface electrodes 2 obtained in Comparative Examples 10 and 11 had sheet resistance values of 9.0 Ω/sq. and 8.9 Ω/sq., respectively. However, in Comparative Example 10, the surface electrode 2 had a low haze ratio of 7%. Furthermore, in Comparative Example 11, the surface electrode 2 had a very low transmittance of 77.9%.

Furthermore, using the respective surface electrodes 2 formed in Comparative Examples 10 and 11, the respective thin film solar cells were formed in the same manner as in Example 1, and the characteristics thereof were evaluated. As a result, the respective thin film solar cells formed in Comparative Examples 10 and 11 had a low photoelectric conversion efficiency of 9.3%.

### Comparative Examples 12 and 13

In Comparative Examples 12 and 13, the respective surface electrodes 2 were formed in the same manner as in Example 1 and the characteristics thereof were evaluated, except that rough films 22 constituting the surface electrodes 2 formed in Comparative Examples 12 and 13 had film thicknesses of 400 nm and 1500 nm, respectively. Table 2 shows the respective evaluation results.

As shown in Table 2, the surface electrodes 2 obtained in Comparative Examples 12 and 13 had sheet resistance values of 8.2 Ω/sq. and 8.3 Ω/sq., respectively. However, the respective surface electrodes 2 had a low haze ratio of 7%. Furthermore, in Comparative Example 13, the surface electrode 2 had a very low transmittance of 75.6%.

Furthermore, using the respective surface electrodes 2 formed in Comparative Examples 12 and 13, thin film solar cells were formed in the same manner as in Example 1, and the characteristics thereof were evaluated. As a result, the thin film solar cells formed in Comparative Examples 12 and 13 had low photoelectric conversion efficiencies of 9.5% and 9.3%, respectively.

### Comparative Examples 14 to 16

In Comparative Examples 14 and 15, the respective surface electrodes 2 were formed in the same manner as in Example 1 and the characteristics thereof were evaluated, except that the respective ISiO films each constituting a low-refractive-index transparent thin film 5 had a film thickness of 100 nm, and the respective base films 21 which are constituents of the respective surface electrodes 2 had film thicknesses of 40 nm and 250 nm. In Comparative Example 16, a surface electrode 2 was formed in the same manner as in Example 1 and the characteristics thereof were evaluated, except that an ISiO film constituting a low-refractive-index transparent thin film 5 had a film thickness of 100 nm, and a rough film 22 which was a constituent of the surface electrode 2 had a film thickness of 400 nm. Table 2 shows the respective evaluation results.

As shown in Table 2, the surface electrodes 2 obtained in Comparative Examples 14 to 16 had sheet resistance values of 8.1 Ω/sq., 8.2 Ω/sq., and 8.4 Ω/sq., respectively. However, the surface electrodes 2 obtained in Comparative Examples 14 and 15 had very low haze ratios of 3% and 2%, respectively. Furthermore, in Comparative Examples 14 and 16, the surface electrodes 2 had low transmittances of 78.0% and 75.9%.

Furthermore, using the respective surface electrodes 2 formed in Comparative Examples 14 to 16, the respective thin film solar cells were formed in the same manner as in Example 1, and the characteristics thereof were evaluated. As a result, the respective thin film solar cells formed in Comparative Examples 14 to 16 had a low photoelectric conversion efficiencies of 9.3%.

### Comparative Examples 17 to 20

In Comparative Examples 17 and 18, the respective surface electrodes 2 were formed in the same manner as in Example 1 and the characteristics thereof were evaluated, except that the respective ISiO films each constituting a respective low-refractive-index transparent thin film 5 had a film thickness of 150 nm, and the respective base films 21 which were constituents of the surface electrodes 2 obtained in Comparative Examples 17 and 18 had film thicknesses of 40 nm and 250 nm. In Comparative Examples 19 and 20, the respective surface electrodes 2 were formed in the same manner as in Example 1 and the characteristics thereof were evaluated, except that the respective ISiO films each constituting a respective low-refractive-index transparent thin film 5 had a film thickness of 150 nm, and the respective rough films 22 which were constituents of the surface electrodes 2 obtained in Comparative Examples 19 and 20 had film thicknesses of 400 nm and 1500 nm. Table 2 shows the respective evaluation results.

As shown in Table 2, the surface electrodes 2 obtained in Comparative Examples 17 to 20 had sheet resistance values of 7.9 Ω/sq., 9.2 Ω/sq., 9.0 Ω/sq., and 8.9 Ω/sq., respectively. However, the surface electrodes 2 obtained in Comparative Examples 17 to 20 had low haze ratios of 8%, 9%, 10%, and 9%, respectively.

Furthermore, using the respective surface electrodes 2 formed in Comparative Examples 17 to 20, the respective thin film solar cells were formed in the same manner as in Example 1, and the characteristics thereof were evaluated. As a result, the respective thin film solar cells formed in Comparative Examples 17 to 20 had a low photoelectric conversion efficiency of 9.3%.

### Comparative Examples 21 to 23

In Comparative Examples 21 and 22, the respective surface electrodes 2 were formed in the same manner as in Example 1 and the characteristics thereof were evaluated, except that, in the deposition of the low-refractive-index transparent thin film 5, the respective ISiO films having a film thickness of 50 nm were deposited using a sintered compact in which a Si composition was adjusted to 0.5 at a molar ratio with respect to In, and the respective base films 21 which were constituents of the surface electrodes 2 had film thicknesses of 40 nm and 250 nm. In Comparative Example 23, a surface electrode 2 was formed in the same manner as in Example 1 and the characteristics thereof were evaluated, except that, in the deposition of a low-refractive-index transparent thin film 5, an ISiO film having a film thickness of 50 nm was deposited using a sintered compact in which a Si composition was adjusted to 0.5 at a molar ratio with respect to In, and a rough film 22 which was a constituent of the surface electrode 2 had a film thickness of 400 nm. Table 2 shows the respective evaluation results.

As shown in Table 2, the surface electrodes 2 obtained in Comparative Examples 21 to 23 had sheet resistance values of 9.8 Ω/sq., 8.5 Ω/sq., and 9.6 Ω/sq., respectively. However, the respective surface electrodes 2 obtained in Comparative Examples 21 and 23 had a low haze ratio of 7%. In Comparative Example 22, the surface electrode 2 had a low transmittance of 78.6%.

Furthermore, using the respective surface electrodes 2 formed in Comparative Examples 21 to 23, thin film solar cells were formed in the same manner as in Example 1, and the characteristics thereof were evaluated. As a result, the thin film solar cells formed in Comparative Examples 21 to 23 had low photoelectric conversion efficiencies of 9.3%, 8.9%, and 8.6%.

TABLE 1

| | Deposition conditions | | | | Deposition conditions | | | Deposition conditions | | |
|---|---|---|---|---|---|---|---|---|---|---|
| | for first layer | | | | for second layer | | | for third layer | | |
| | | | Film | | | | Film | | | Film |
| | | Si molar | thickness | Roughness | | Temperature | thickness | | Temperature | thickness |
| | Material | ratio | (nm) | (nm) | Material | (° C.) | (nm) | Material | (° C.) | (nm) |
| Example 1 | IsiO | 0.2 | 50 | 0.5 | ITiO | 25 | 100 | GAZO | 300 | 500 |
| Example 2 | ISiO | 0.2 | 50 | 0.6 | ITiO | 25 | 200 | GAZO | 300 | 500 |
| Example 3 | ISiO | 0.2 | 50 | 0.5 | ITiO | 25 | 100 | GAZO | 300 | 1200 |
| Example 4 | ISiO | 0.2 | 50 | 0.5 | ITiO | 25 | 200 | GAZO | 300 | 1200 |
| Example 5 | ISiO | 0.2 | 100 | 0.5 | ITiO | 25 | 100 | GAZO | 300 | 500 |
| Example 6 | ISiO | 0.2 | 100 | 0.6 | ITiO | 25 | 200 | GAZO | 300 | 500 |
| Example 7 | ISiO | 0.2 | 100 | 0.5 | ITiO | 25 | 100 | GAZO | 300 | 1200 |
| Example 8 | ISiO | 0.2 | 100 | 0.5 | ITiO | 25 | 200 | GAZO | 300 | 1200 |
| Example 9 | ISiO | 0.2 | 150 | 0.7 | ITiO | 25 | 100 | GAZO | 300 | 500 |
| Example 10 | ISiO | 0.2 | 150 | 0.8 | ITiO | 25 | 200 | GAZO | 300 | 500 |
| Example 11 | ISiO | 0.2 | 150 | 0.8 | ITiO | 25 | 100 | GAZO | 300 | 1200 |
| Example 12 | ISiO | 0.2 | 150 | 0.9 | ITiO | 25 | 200 | GAZO | 300 | 1200 |
| Example 13 | ISiO | 0.5 | 50 | 0.3 | ITiO | 25 | 100 | GAZO | 300 | 500 |
| Example 14 | ISiO | 0.5 | 50 | 0.2 | ITiO | 25 | 200 | GAZO | 300 | 500 |
| Example 15 | ISiO | 0.5 | 50 | 0.3 | ITiO | 25 | 100 | GAZO | 300 | 1200 |
| Example 16 | ISiO | 0.5 | 50 | 0.3 | ITiO | 25 | 200 | GAZO | 300 | 1200 |
| Example 17 | ISiO | 0.5 | 100 | 0.3 | ITiO | 25 | 100 | GAZO | 300 | 500 |
| Example 18 | ISiO | 0.5 | 100 | 0.3 | ITiO | 25 | 200 | GAZO | 300 | 500 |
| Example 19 | ISiO | 0.5 | 100 | 0.2 | ITiO | 25 | 100 | GAZO | 300 | 1200 |
| Example 20 | ISiO | 0.5 | 100 | 0.4 | ITiO | 25 | 200 | GAZO | 300 | 1200 |
| Example 21 | ISiO | 0.5 | 150 | 0.7 | ITiO | 25 | 100 | GAZO | 300 | 500 |
| Example 22 | ISiO | 0.5 | 150 | 0.6 | ITiO | 25 | 200 | GAZO | 300 | 500 |
| Example 23 | ISiO | 0.5 | 150 | 0.7 | ITiO | 25 | 100 | GAZO | 300 | 1200 |
| Example 24 | ISiO | 0.5 | 150 | 0.7 | ITiO | 25 | 200 | GAZO | 300 | 1200 |
| Comparative Example 1 | ISiO | 0.2 | 30 | 0.6 | ITiO | 25 | 100 | GAZO | 300 | 500 |
| Comparative Example 2 | ISiO | 0.2 | 200 | 1.1 | ITiO | 25 | 100 | GAZO | 300 | 500 |
| Comparative Example 3 | ISiO | 0.5 | 30 | 0.2 | ITiO | 25 | 100 | GAZO | 300 | 500 |
| Comparative Example 4 | ISiO | 0.5 | 200 | 1.2 | ITiO | 25 | 100 | GAZO | 300 | 500 |
| Comparative Example 5 | ISiO | 0.1 | 50 | 0.6 | ITiO | 25 | 100 | GAZO | 300 | 500 |
| Comparative Example 6 | ISiO | 0.1 | 150 | 1.2 | ITiO | 25 | 100 | GAZO | 300 | 500 |
| Comparative Example 7 | ISiO | 0.6 | 50 | 0.3 | ITiO | 25 | 100 | GAZO | 300 | 500 |
| Comparative Example 8 | ISiO | 0.6 | 150 | 0.3 | ITiO | 25 | 100 | GAZO | 300 | 500 |
| Comparative Example 9 | — | — | — | — | ITiO | 25 | 100 | GAZO | 300 | 500 |
| Comparative Example 10 | ISiO | 0.2 | 50 | 0.5 | ITiO | 25 | 40 | GAZO | 300 | 500 |
| Comparative Example 11 | ISiO | 0.2 | 50 | 0.5 | ITiO | 25 | 250 | GAZO | 300 | 500 |
| Comparative Example 12 | ISiO | 0.2 | 50 | 0.6 | ITiO | 25 | 100 | GAZO | 300 | 400 |
| Comparative Example 13 | ISiO | 0.2 | 50 | 0.5 | ITiO | 25 | 100 | GAZO | 300 | 1500 |
| Comparative Example 14 | ISiO | 0.2 | 100 | 0.6 | ITiO | 25 | 40 | GAZO | 300 | 500 |
| Comparative Example 15 | ISiO | 0.2 | 100 | 0.6 | ITiO | 25 | 250 | GAZO | 300 | 500 |
| Comparative Example 16 | ISiO | 0.2 | 100 | 0.6 | ITiO | 25 | 100 | GAZO | 300 | 400 |
| Comparative Example 17 | ISiO | 0.2 | 150 | 0.9 | ITiO | 25 | 40 | GAZO | 300 | 500 |
| Comparative Example 18 | ISiO | 0.2 | 150 | 0.8 | ITiO | 25 | 250 | GAZO | 300 | 500 |
| Comparative Example 19 | ISiO | 0.2 | 150 | 0.7 | ITiO | 25 | 100 | GAZO | 300 | 400 |
| Comparative Example 20 | ISiO | 0.2 | 150 | 0.7 | ITiO | 25 | 100 | GAZO | 300 | 1500 |
| Comparative Example 21 | ISiO | 0.5 | 50 | 0.2 | ITiO | 25 | 40 | GAZO | 300 | 500 |
| Comparative Example 22 | ISiO | 0.5 | 50 | 0.2 | ITiO | 25 | 250 | GAZO | 300 | 500 |
| Comparative Example 23 | ISiO | 0.5 | 50 | 0.3 | ITiO | 25 | 100 | GAZO | 300 | 400 |

TABLE 2

| | | | | | Cell characteristics |
|---|---|---|---|---|---|
| | Refractive index of | Surface electrode Characteristics | | | Photoelectric |
| | low-refractive-index | Sheet resistance | | Transmittance | conversion |
| | transparent thin film | (Ω/sq.) | Haze ratio (%) | (%) | efficiency (%) |
| Example 1 | 1.8 | 9.1 | 15 | 82.0 | 10.3 |
| Example 2 | 1.8 | 8.5 | 18 | 82.0 | 10.3 |
| Example 3 | 1.8 | 8.8 | 20 | 82.0 | 10.5 |
| Example 4 | 1.8 | 8.3 | 21 | 82.0 | 10.4 |
| Example 5 | 1.8 | 8.8 | 15 | 82.7 | 10.6 |
| Example 6 | 1.8 | 8.7 | 16 | 82.6 | 10.7 |
| Example 7 | 1.8 | 8.8 | 23 | 82.6 | 10.6 |
| Example 8 | 1.8 | 8.9 | 22 | 82.7 | 10.6 |
| Example 9 | 1.8 | 8.6 | 17 | 83.0 | 10.4 |
| Example 10 | 1.8 | 8.9 | 18 | 82.8 | 10.4 |
| Example 11 | 1.8 | 8.7 | 20 | 82.7 | 10.4 |
| Example 12 | 1.8 | 8.5 | 21 | 83.1 | 10.4 |
| Example 13 | 1.65 | 8.3 | 20 | 85.1 | 10.8 |
| Example 14 | 1.65 | 8.2 | 21 | 85.1 | 10.8 |
| Example 15 | 1.65 | 8.0 | 22 | 85.1 | 10.7 |
| Example 16 | 1.65 | 8.8 | 20 | 85.1 | 10.8 |
| Example 17 | 1.65 | 8.2 | 18 | 85.3 | 10.4 |
| Example 18 | 1.65 | 7.8 | 19 | 85.4 | 10.4 |
| Example 19 | 1.65 | 9.0 | 14 | 85.3 | 10.4 |
| Example 20 | 1.65 | 7.7 | 17 | 85.5 | 10.4 |
| Example 21 | 1.65 | 8.6 | 15 | 85.7 | 10.8 |
| Example 22 | 1.65 | 8.7 | 13 | 85.7 | 10.9 |
| Example 23 | 1.65 | 8.9 | 14 | 85.7 | 10.3 |
| Example 24 | 1.65 | 8.7 | 18 | 85.5 | 10.6 |
| Comparative Example 1 | 1.8 | 8.3 | 9 | 82.0 | 9.2 |
| Comparative Example 2 | 1.8 | 8.2 | 7 | 82.2 | 9.2 |
| Comparative Example 3 | 1.65 | 8.3 | 7 | 84.5 | 9.3 |
| Comparative Example 4 | 1.65 | 8.1 | 3 | 84.2 | 9.3 |
| Comparative Example 5 | 1.9 | 8.1 | 3 | 80.2 | 9.1 |
| Comparative Example 6 | 1.9 | 8.2 | 2 | 80.1 | 9.1 |
| Comparative Example 7 | 1.55 | 8.4 | 7 | 79.8 | 9.0 |
| Comparative Example 8 | 1.55 | 7.9 | 8 | 79.7 | 9.0 |
| Comparative Example 9 | — | — | — | 78.5 | 8.7 |
| Comparative Example 10 | 1.8 | 9.0 | 7 | 82.0 | 9.3 |
| Comparative Example 11 | 1.8 | 8.9 | 16 | 77.9 | 9.3 |
| Comparative Example 12 | 1.8 | 8.2 | 7 | 82.0 | 9.5 |
| Comparative Example 13 | 1.8 | 8.3 | 7 | 75.6 | 9.3 |
| Comparative Example 14 | 1.65 | 8.1 | 3 | 78.0 | 9.3 |
| Comparative Example 15 | 1.65 | 8.2 | 2 | 82.1 | 9.3 |
| Comparative Example 16 | 1.65 | 8.4 | 22 | 75.9 | 9.3 |
| Comparative Example 17 | 1.8 | 7.9 | 8 | 80.0 | 9.3 |
| Comparative Example 18 | 1.8 | 9.2 | 9 | 81.0 | 9.3 |
| Comparative Example 19 | 1.8 | 9.0 | 10 | 80.3 | 9.3 |
| Comparative Example 20 | 1.8 | 8.9 | 9 | 79.9 | 9.3 |
| Comparative Example 21 | 1.55 | 9.8 | 7 | 80.2 | 9.3 |
| Comparative Example 22 | 1.55 | 8.5 | 26 | 78.6 | 8.9 |
| Comparative Example 23 | 1.55 | 9.6 | 7 | 80.2 | 8.6 |

### REFERENCE SYMBOLS

1 . . . translucent glass substrate, 2 . . . surface electrode, 21 . . . base film, 22 . . . rough film, 22a . . . surface roughness structure, 3 . . . photoelectric conversion semiconductor layer, 31 . . . p-type semiconductor layer, 32 . . . i-type semiconductor layer, 33 . . . n-type semiconductor layer, 4 . . . back surface electrode, 41 . . . transparent conductive oxide, 42 . . . light reflective metal electrode, and 5 . . . low-refractive-index film.

1. A transparent conductive glass substrate with a surface electrode, wherein, on a translucent glass substrate, a low-refractive-index transparent thin film having a refractive index of 1.6 to 1.8 at a wavelength of 550 nm and having a film thickness of 50 nm to 150 nm is formed as a first layer, and an amorphous indium-oxide-based transparent conductive film as a second layer and a rough film made of a crystalline zinc-oxide-based transparent conductive film as a third layer are formed in that order on the low-refractive-index transparent thin film.

2. The transparent conductive glass substrate with the surface electrode according to claim 1, wherein the low-refractive-index transparent thin film constituting the first layer is an oxide film having indium and silicon as main components, and has a molar ratio of silicon to indium of from 0.2 to 0.5.

3. The transparent conductive glass substrate with the surface electrode according to claim 1, wherein the low-refractive-index transparent thin film constituting the first layer is an oxide film having indium and silicon as main components, has a molar ratio of silicon to indium of from 0.2 to 0.5, and has smoothness with a surface roughness Ra of not more than 1.0 nm.

4. The transparent conductive glass substrate with the surface electrode according to claim 1, wherein
the amorphous indium-oxide-based transparent conductive film constituting the second layer is made of indium oxide doped with Ti, and
the crystalline zinc-oxide-based transparent conductive film constituting the third layer is made of zinc oxide doped with Al and/or Ga.

5. The transparent conductive glass substrate with the surface electrode according to claim 1, wherein the amorphous indium-oxide-based transparent conductive film has a film thickness of 100 nm to 200 nm.

6. The transparent conductive glass substrate with the surface electrode according to claim 1, wherein the crystalline zinc-oxide-based transparent conductive film has a film thickness of 500 nm to 1200 nm.

7. A method for producing a transparent conductive glass substrate with a surface electrode, comprising:
a low-refractive-index transparent thin film formation step, wherein, on a translucent glass substrate, a low-refractive-index transparent thin film having a refractive index of 1.6 to 1.8 at a wavelength of 550 nm and having a film thickness of 50 nm to 150 nm is formed as a first layer by sputtering; and
a surface electrode formation step, wherein, on the low-refractive-index transparent thin film, with a temperature of the translucent glass substrate being maintained in a range of not less than a room temperature and not more than 50° C., an amorphous indium-oxide-based transparent conductive film is formed as a second layer by sputtering, and then, with a temperature of the translucent glass substrate being maintained in a range of 250° C. to 400° C., a rough film made of a crystalline zinc-oxide-based transparent conductive film is formed as a third layer by sputtering.

8. A thin film solar cell, comprising:
a transparent conductive glass substrate with a surface electrode, the transparent conductive glass substrate being configured such that, on a translucent glass substrate, a low-refractive-index transparent thin film having a refractive index of 1.6 to 1.8 at a wavelength of 550 nm and having a film thickness of 50 nm to 150 nm is formed as a first layer, and, on the low-refractive-index transparent thin film, an amorphous indium-oxide-based transparent conductive film as a second layer and a rough film made of a crystalline zinc-oxide-based transparent conductive film as a third layer are formed in that order;
a photoelectric conversion semiconductor layer; and
a back surface electrode including at least a light reflective metal electrode,
wherein the transparent conductive glass substrate with a surface electrode, the photoelectric conversion semiconductor layer, and the back surface electrode are formed in that order.

9. A method for manufacturing a thin film solar cell, the thin film solar cell comprising: a transparent conductive glass substrate with a surface electrode; a photoelectric conversion semiconductor layer; and a back surface electrode including at least a light reflective metal electrode, wherein the transparent conductive glass substrate, the photoelectric conversion semiconductor layer, and the back surface electrode are formed in that order,
the method including a step of forming the transparent conductive glass substrate with the surface electrode,
the step comprising:
a low-refractive-index transparent thin film formation step, wherein, on a translucent glass substrate, a low-refractive-index transparent thin film having a refractive index of 1.6 to 1.8 at a wavelength of 550 nm and having a film thickness of 50 nm to 150 nm is formed as a first layer by sputtering; and
a surface electrode formation step, wherein, on the low-refractive-index transparent thin film, with a temperature of the translucent glass substrate being maintained in a range of not less than a room temperature and not more than 50° C., an amorphous indium-oxide-based transparent conductive film is formed as a second layer by sputtering, and then, with a temperature of the translucent glass substrate being maintained in a range of 250° C. to 400° C., a rough film made of a crystalline zinc-oxide-based transparent conductive film is formed as a third layer by sputtering.
